(19) United States
(12) Patent Application Publication
(10) Pub. No.: US 2025/0132181 A1
(43) Pub. Date: Apr. 24, 2025

(54) SEMICONDUCTOR PROCESSING ASSEMBLY AND METHOD FOR TRANSFERRING WAFERS

(71) Applicant: ASM IP Holding B.V., Almere (NL)

(72) Inventors: Theodorus G.M. Oosterlaken, Oudewater (NL); Nimit Kothari, Almere (NL); Marina de Jager, Dronten (NL)

(21) Appl. No.: 18/915,971

(22) Filed: Oct. 15, 2024

Related U.S. Application Data
(60) Provisional application No. 63/591,595, filed on Oct. 19, 2023.

(51) Int. Cl. H01L 21/677; B25J 11/00; B25J 15/06; H01L 21/673; H01L 21/683; H01L 21/687

(52) U.S. Cl. CPC H01L 21/67781; B25J 11/0095; B25J 15/0625; H01L 21/6732; H01L 21/67383; H01L 21/6838; H01L 21/68707

(57) ABSTRACT

A semiconductor processing assembly is disclosed with: a wafer handling robot comprising a plurality of end effectors distributed in substantial vertical direction at an end effector pitch and configured to carry wafers; a wafer boat having boat slots distributed in substantial vertical direction and configured to hold wafers to be loaded at a load pitch; a wafer cassette having cassette slots distributed in substantial vertical direction at a cassette pitch and configured to hold wafers; and an electronic controller for controlling at least the wafer handling robot and having a system memory. By having the end effector pitch substantially equal to the cassette pitch, the electronic controller may be configured and programmed with a program in its system memory to control the semiconductor processing assembly to transfer wafers between the cassette slots of the wafer cassette and the boat slots of the wafer boat.

### CROSS-REFERENCE TO RELATED APPLICATION(S)

This Application claims the benefit of U.S. Provisional Application 63/591,595 filed on Oct. 19, 2023, the entire contents of which are incorporated herein by reference.

### FIELD OF INVENTION

The present disclosure generally relates to a semiconductor processing assembly. It may more particularly relate to a semiconductor processing assembly with:
a wafer handling robot comprising a plurality of end effectors distributed in substantial vertical direction at an end effector pitch and configured to carry wafers;
a wafer boat having boat slots distributed in substantial vertical direction and configured to hold wafers to be loaded at a load pitch;
a wafer cassette having cassette slots distributed in substantial vertical direction at a cassette pitch and configured to hold wafers; and,
an electronic controller for controlling at least the wafer handling robot and having a system memory.

### BACKGROUND

Most semiconductor processing assemblies may be provided with a wafer handling robot to transfer wafers between the cassette slots of the wafer cassette and the boat slots of the wafer boat. Such a wafer handling robot may be configured for precisely placing a wafer in a slot of the wafer cassette or the wafer boat. Since the end effector pitch of the wafer handling robot may be equal to the cassette pitch but unequal to the load pitch there may be a need to adapt the assembly for an efficient loading method to transfer wafers between the wafer cassette and the wafer boat.

### SUMMARY

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

It is realized that the movements of a wafer handling robot with respect to a wafer cassette and wafer boat may need to be very accurate.

It may be an object to provide an assembly and method for transferring wafers between the wafer cassette and the wafer boat.

To that end, there may be provided an assembly according to claim 1. More particularly, there may be provided a semiconductor processing assembly comprising:
a wafer handling robot comprising a plurality of end effectors distributed in substantial vertical direction at an end effector pitch and configured to carry wafers;
a wafer boat having boat slots distributed in substantial vertical direction and configured to hold wafers to be loaded at a load pitch in the wafer boat;
a wafer cassette having cassette slots distributed in substantial vertical direction at a cassette pitch and configured to hold wafers; and,
an electronic controller for controlling at least the wafer handling robot and having a system memory. The end effector pitch may be equal to the cassette pitch but unequal to the load pitch. Transferring wafers between the wafer cassette and the wafer boat may be controlled by the electronic controller. The electronic controller may be configured and programmed with a program in its system memory to control the semiconductor processing assembly to transfer a plurality of wafers according to a method. The method may comprise transferring a plurality of wafers simultaneously between the cassette slots of the wafer cassette and the end effectors of the wafer handling robot. The method may comprise transferring only one wafer at a time between the end effectors of the wafer handling robot and one boat slot of the wafer boat.

There may also be provided a method for transferring of wafers according to claim 9. More particularly, there may be provided a method for transferring of wafers in a semiconductor processing assembly comprising:
a wafer handling robot comprising a plurality of end effectors distributed in substantial vertical direction at an end effector pitch and configured to carry wafers;
a wafer boat having boat slots distributed in substantial vertical direction and configured to hold wafers to be loaded at a load pitch;
a wafer cassette having cassette slots distributed in substantial vertical direction at a cassette pitch and configured to hold wafers; and,
an electronic controller for controlling at least the wafer handling robot and having a system memory; wherein the end effector pitch is equal to the cassette pitch but unequal to the load pitch, the following method is performed under control of the electronic controller of the semiconductor processing assembly:
transferring a plurality of wafers simultaneously between the cassette slots of the wafer cassette and the end effectors of the wafer handling robot; and,
transferring only one wafer a time between the end effectors of the wafer handling robot and one boat slot of the wafer boat.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

Various embodiments are claimed in the dependent claims, which will be further elucidated with reference to an example shown in the figures. The embodiments may be combined or may be applied separate from each other.

The embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE FIGURES

While the specification concludes with claims particularly pointing out and distinctly claiming what are regarded as embodiments of the invention, the advantages of embodiments of the disclosure may be more readily ascertained from the description of certain examples of the embodiments of the disclosure when read in conjunction with the accompanying drawings, in which:

FIG. 1 shows a schematic cross sectional top view of an example of an semiconductor processing assembly according to the description;

FIG. 2A shows a schematic cross-sectional side view of an example of a wafer handling robot, a wafer boat and a wafer cassette for the semiconductor processing assembly of FIG. 1;

FIG. 2B shows a partial schematic enlarged side view of an end effector of the wafer handling robot of FIG. 2A;

FIG. 2C shows a partial schematic enlarged side view of the wafer cassette of the semiconductor processing assembly of FIG. 2A;

FIG. 3 shows a partial schematic enlarged side view of an end effector for the wafer handling robot of FIG. 2A according to a further embodiment;

FIG. 4 shows a schematic side view of a wafer boat for the semiconductor processing assembly of FIG. 1; and,

FIG. 5 shows a flow chart for the handling of wafers by the semiconductor processing assembly of FIG. 2A.

### DETAILED DESCRIPTION

In this application similar or corresponding features are denoted by similar or corresponding reference signs. The description of the various embodiments is not limited to the example shown in the figures and the reference numbers used in the detailed description and the claims are not intended to limit the description of the embodiments but are included to elucidate the embodiments.

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below. The illustrations presented herein are not meant to be actual views of any particular material, structure, or device, but are merely idealized representations that are used to describe embodiments of the disclosure.

As used herein, the term “wafer” may refer to any underlying material or materials that may be used, or upon which, a device, a circuit, or a film may be formed.

In the most general terms, the present disclosure may provide an assembly and method for transferring wafers between the wafer cassette (40) and the wafer boat (20).

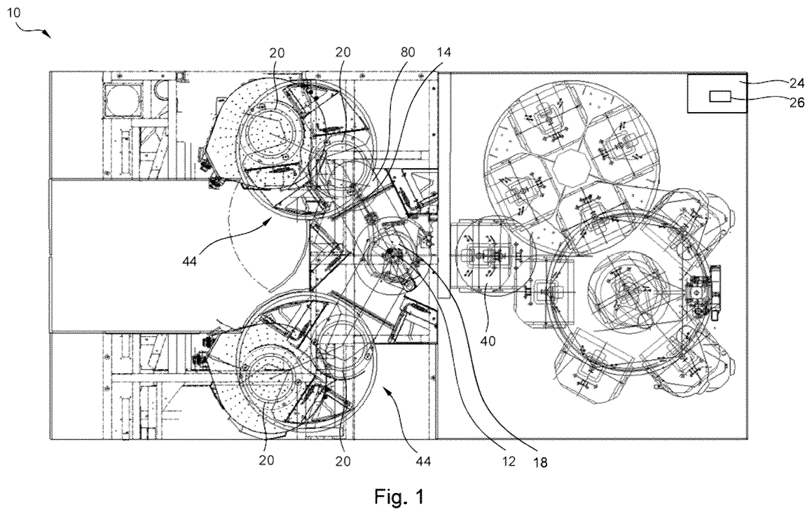

FIG. 1 shows a schematic cross sectional top view of an example of a semiconductor processing assembly according to the description. The semiconductor processing assembly (10) may comprise: a wafer handling robot (12) comprising a plurality of end effectors (14) to carry wafers (80); a wafer boat (20) having boat slots distributed in substantial vertical direction and configured to hold wafers (80) to be loaded in the wafer boat (20); a wafer cassette (40) having cassette slots configured to hold wafers (80); and, an electronic controller (24) for controlling at least the wafer handling robot (12) and having a system memory (26). The assembly may also have a wafer centre finder (18) to find a centre of the wafer (80) to facilitate precise handling of it.

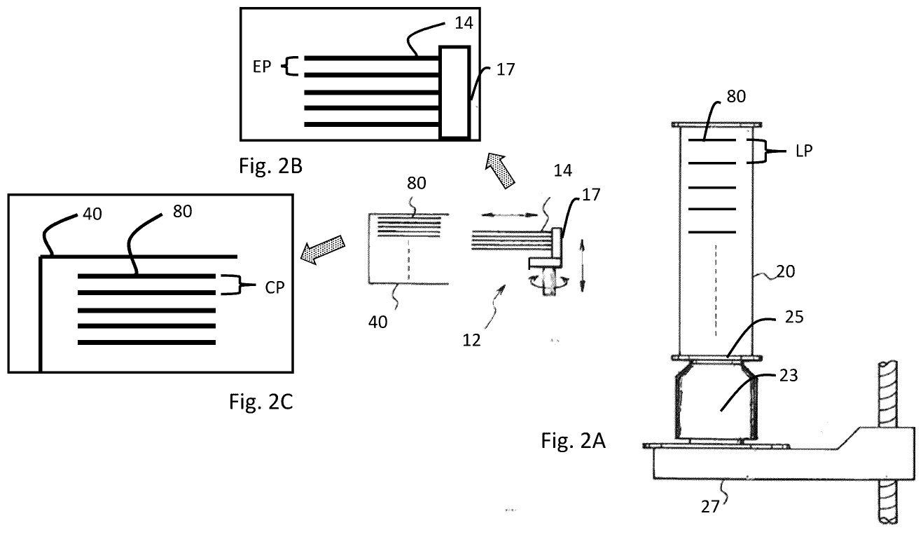

FIG. 2A shows a schematic cross-sectional side view of an example of a wafer handling robot (with a partial enlargement of the end effector 14 in FIG. 2B), a wafer boat (20) and a wafer cassette (40) (with a partial enlargement in FIG. 2C).

The wafers (80) may be transferred between the wafer cassette (40) and the wafer boat (20) by the wafer handling robot (12) by supporting the wafers at the end effectors (14). The end effectors (14) of the wafer handling robot (12) may be distributed in substantial vertical direction at an end effector pitch (See FIG. 2B (EP)). The wafers (80) may therefore be distributed in substantial vertical direction at the end effector pitch (EP) while being transferred by the end effectors (14) of the wafer handling robot (12).

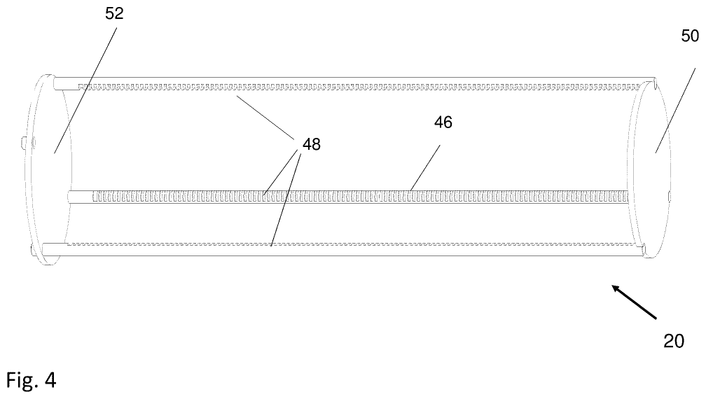

The wafer boat (20) may have boat slots (See FIG. 4 (46)) formed in a boat rail (48) and distributed in substantial vertical direction at a boat pitch and configured to hold wafers (80) to be loaded at a load pitch (LP) in the wafer boat (20). The load pitch (LP) may be different than the boat pitch. For example, the boat pitch may be between 0.5 and 1.5 cm while the load pitch (LP) may be between 0.5 and 10 cm, preferably between 0.5 and 5 cm depending on the process. This means that a number of slots (46) in between wafers (80) in the wafer boat (20) may be left without wafer. This may be beneficial for the within wafer uniformity of the process in the reactor. It may also lead to less wafers processed in once.

The wafer boat (20) may have a top plate (50) and a bottom plate (52). The bottom plate (52) of the wafer boat (20) may be supported on a pedestal (23) and a doorplate (25) in the assembly of FIG. 2A. The wafer boat 20 is movable by an elevator (27) into a reaction chamber not shown.

The wafer cassette (40) may be a FOUP, in which the wafer slots 46 are situated between two side walls. The wafer cassette (40) may have cassette slots distributed in substantial vertical direction at a cassette pitch (CP) and configured to hold wafers (80). The semiconductor processing assembly (10) may have the end effector pitch (EP) equal to the cassette pitch (CP) to facilitate easy handling of the wafers (80).

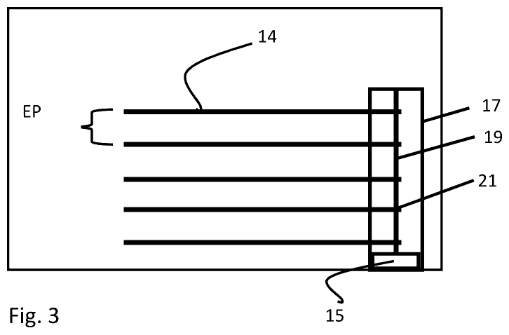

FIG. 3 shows a partial schematic enlarged side view of an end effector for the wafer handling robot of FIG. 2A according to a further embodiment with an adjustable pitch (EP). The wafer handling robot (12) may be provided with a pitch motor (15) in a moveable housing (17). The moveable housing (17) may be moveable by the wafer handling robot (12) in X, Z and Rz as depicted by the arrows. The pitch motor 15 may be operably connected to the electronic controller (24) to adjust the end effector pitch (EP) in substantial vertical direction parallel to the Z direction. The pitch motor (15) may be operably connected to a spindle (19) in the moveable housing (17) which may be rotated by the pitch motor (15). The spindle (19) may comprise a helical thread cooperating with a nut (21) mounted to the end effector (14). The helical thread and the nut (21) may be selected and/or formed to move the end effectors (14) when the spindle is rotated to change the end effector pitch (EP). The end effector (14) may be slidably mounted in the moveable housing (17) of the wafer handling robot (12) to accommodate movement of the end effectors (14). The spindle (19) and the electronic controller (24) may be configured and programmed with a program in its system memory (26) to adapt the end effector pitch (EP) of all the end effectors (14). Alternatively, multiple spindles (19) and/or pitch motors (15) may change the end effector pitch (EP).

The end effector pitch (EP) may be adapted to substantially match the cassette pitch (CP). If the end effector pitch (EP) and the cassette pitch (CP) substantially match it becomes possible to transfer a plurality of wafers simultaneously. For example, for wafer transfer between the cassette slots of the wafer cassette (40) and the end effectors (14) of the wafer handling robot in one move multiple wafers (80) may be picked up or let down. The electronic controller (24) may therefore be configured and programmed with a program in its system memory (26) to control the semiconductor processing assembly (10) to transfer a plurality of wafers simultaneously between the cassette slots of the wafer cassette (40) and the end effectors (14) of the wafer handling robot (12) by having the end effector pitch (EP) of the wafer handling robot (12) substantially match with the cassette pitch (CP) saving time.

The end effector pitch (EP) may also be adapted to substantially match the load pitch (LP) of the wafer boat (20). If the end effector pitch (EP) and the load pitch (LP) substantially match it may become possible to transfer a plurality of wafers simultaneously between the wafer boat (20) and the end effectors (14).

If the load pitch (LP) becomes large and the end-effector pitch (EP) may not be adaptable to the load pitch (LP) it may be necessary to perform the transfer differently. This may be done by transferring only one wafer a time between the end effectors (14) of the wafer handling robot (12) and one boat slot (46) of the wafer boat (20) to accommodate the load pitch (LP) for the wafer boat (20).

In this way it becomes possible to quickly pick up multiple wafers (80) from the wafer cassette (40) in one move and then place the wafers (80) in the wafer boat (20) one by one at the correct load pitch (LP). This saves time compared to a situation where only one wafer from the wafer cassette (40) is loaded on the end effector (14) and from there only one wafer (80) is placed in the wafer boat (20) and thereafter returning to the wafer cassette (40) to pick up the next wafer (80).

The electronic controller (24) may be configured and programmed with a program in its system memory (26) to control the semiconductor processing assembly (10) to:
move the end effectors (14) of the wafer handling robot (12) in between a plurality of wafers (80) in the wafer cassette (40) and move the end effectors (14) up to place a plurality of wafers on the end effectors (14) and retreat the end effectors (14) from the wafer cassette (40);
move the end effectors (14) carrying wafers in between the boat slots (46) of the wafer boat (20) and move the end effectors (14) down to leave a first wafer of the wafers on the end effectors (14) in the one boat slot in the wafer boat and retreat the end effectors (14) from the wafer boat (20);
move the end effectors (14) carrying wafers in between the boat slots (46) of the wafer boat (20) and move the end effectors (14) down to leave a second wafer of the wafer(s) on the end effectors (14) in a second wafer slot in the wafer boat and retreat the end effectors (14) from the wafer boat (20). In this way it becomes possible to pick up two wafers (80) from the wafer cassette (40) on two end effectors (14) in one move and then place the two wafers (80) in the wafer boat (20) one by one at the correct load pitch (LP) saving time.

The electronic controller (24) may be configured and programmed with a program in its system memory to control the semiconductor processing assembly (10) to:

move the end effectors (14) carrying wafers in between the boat slots (46) of the wafer boat (20) and move the end effectors (14) down to leave a third wafer of the wafer(s) on the end effectors (14) in a third boat slot in the wafer boat and retreat the end effectors (14) from the wafer boat (20). In this way it becomes possible to quickly pick up three wafers (80) from the wafer cassette (40) on three end effectors (14) in one move and then place the three wafers (80) in the wafer boat (20) one by one at the correct load pitch (LP) saving time.

The electronic controller (24) may be configured and programmed with a program in its system memory to control the semiconductor processing assembly (10) to move the end effectors (14) carrying wafers in between the boat slots (46) of the wafer boat (20) and move the end effectors (14) down to leave a fourth wafer of the wafer(s) on the end effectors (14) in a fourth boat slot in the wafer boat and retreat the end effectors (14) from the wafer boat (20). In this way it becomes possible to quickly pick up four wafers (80) from the wafer cassette (40) on four end effectors (14) in one move and then place the four wafers (80) in the wafer boat (20) one by one at the correct load pitch (LP) saving time.

The electronic controller (24) may be configured and programmed with a program in its system memory to control the semiconductor processing assembly (10) to move the end effectors (14) carrying wafers in between the boat slots (46) of the wafer boat (20) and move the end effectors (14) down to leave a fifth wafer of the wafer(s) on the end effectors (14) in a fifth boat slot in the wafer boat and retreat the end effectors (14) from the wafer boat (20). In this way it becomes possible to quickly pick up five wafers (80) from the wafer cassette (40) on five end effectors (14) in one move and then place the five wafers (80) in the wafer boat (20) one by one at the correct load pitch (LP) saving time.

The semiconductor processing assembly may further comprise (see FIG. 1) a plurality of wafer boats (20). The wafer boats (20) may each be moveable to a wafer loading position (44) in which wafers (80) can be loaded by the wafer handling robot (12) in the respective wafer boat (20). The electronic controller (24) may be configured and programmed with a program in its system memory to control the semiconductor processing assembly (10) to transfer wafers from the wafer cassette (40) to the wafer boat (20), for each wafer boat (20) when it is positioned in the wafer loading position (44). The memory may be programmed with the load pitch (LP) of each one of the plurality of wafer boats (20) when it is positioned in the wafer loading position (44).

For transferring wafers from the wafer boat (20) to the wafer cassette (40), the electronic controller (24) may be configured and programmed with a program in its system memory to control the semiconductor processing assembly (10) to:
move the end effectors (14) in between the wafers in the boat slots (46) of the wafer boat (20) and move the end effectors (14) up to pick a first wafer from a boat slot in the wafer boat and retreat the end effectors (14) with the first wafer from the wafer boat (20);
move the end effectors (14) in between the wafers in the boat slots (46) of the wafer boat (20) and move the end effectors (14) up to pick up a second wafer on a wafer slot in the wafer boat and retreat the end effectors (14) with the second wafer from the wafer boat (20);
move the end effectors (14) of the wafer handling robot (12) in between the cassette slots in the wafer cassette (40) and move the end effectors (14) down to place a plurality of wafers in the cassette slots and retreat the end effectors (14) from the wafer cassette (40). In this way it becomes possible to pick up two wafers (80) from the wafer boat (20) at the correct load pitch (LP) one by one on two end effectors (14) and quickly place the two wafers (80) from the two end effectors (14) in the wafer cassette (40) in one move saving time.

In an embodiment the end effector 14 may have a vacuum clamp including a vacuum plenum in the wafer support surface 16. The vacuum plenum may be connectable to a vacuum source. The vacuum clamp may be switched on under control of the controller (24) so as to connect the vacuum plenum with the vacuum source and may be switched off so that the vacuum plenum is disconnected from the vacuum source. The vacuum clamp may be switched off under control of the controller (24) when the end effectors (14) move down to leave a first wafer on a boat slot in the wafer boat (20). The vacuum clamp may provide a strong and reliable way to hold wafers (80) on the end effectors (14) during transfer.

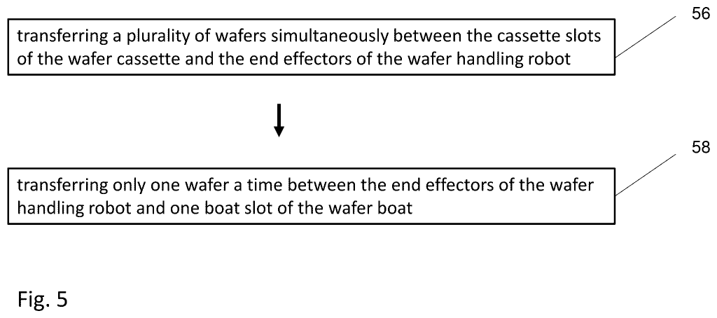

FIG. 5 shows a flow chart for the handling of wafers by the semiconductor processing assembly of FIG. 2A according to an embodiment. The method of handling wafers comprises:
transferring (56) a plurality of wafers simultaneously between the cassette slots of the wafer cassette (40) and the end effectors (14) of the wafer handling robot (12) by having the end effector pitch substantially match the cassette pitch (CP); and,
transferring (58) only one wafer a time between the end effectors (14) of the wafer handling robot (12) and one boat slot (46) of the wafer boat (20) to accommodate the load pitch (LP) for the wafer boat (20). In this way it becomes possible to pick up two wafers (80) from the wafer cassette (40) on two end effectors (14) in one move and then place the two wafers (80) in the wafer boat (20) one by one at the correct load pitch (LP). This saves time compared to a situation where only one wafer from the wafer cassette (40) is loaded on the end effector (14) and from there only one wafer (80) is placed in the wafer boat (20) and thereafter returning to the wafer cassette (40) to pick up the next wafer (80).

The method may comprise:
moving the end effectors (14) of the wafer handling robot (12) in between a plurality of wafers (80) in the wafer cassette (40) and move the end effectors (14) up to place a plurality of wafers on the end effectors (14) and retreat the end effectors (14) from the wafer cassette (40);
moving the end effectors (14) carrying wafers in between the boat slots (46) of the wafer boat (20) and move the end effectors (14) down to leave a first wafer of the wafer(s) on the end effectors (14) in a boat slot in the wafer boat and retreat the end effectors (14) from the wafer boat (20); and directly thereafter;
moving the end effectors (14) carrying wafers in between the boat slots (46) of the wafer boat (20) and move the end effectors (14) down to leave a second wafer of the wafer(s) on the end effectors (14) in a wafer slot in the wafer boat and retreat the end effectors (14) from the wafer boat (20). In this way it becomes possible to pick up two wafers (80) from the wafer cassette (40) on two end effectors (14) in one move and then place the two wafers (80) in the wafer boat (20) one by one at the correct load pitch (LP) saving time.

The method may further comprise moving the end effectors (14) carrying wafers in between the boat slots (46) of the wafer boat (20) and move a wafer support surfaces (16) of the end effector (14) down to leave a third wafer on a wafer slot in the wafer boat and retreat the end effectors (14) from the wafer boat (20). In this way it becomes possible to quickly pick up three wafers (80) from the wafer cassette (40) on three end effectors (14) in one move and then place the three wafers (80) in the wafer boat (20) one by one at the correct load pitch (LP) saving time.

The method may further comprise moving the end effectors (14) carrying wafers in between the boat slots (46) of the wafer boat (20) and move the end effectors (14) down to leave a fourth wafer on a wafer slot in the wafer boat (20) and retreat the end effectors (14) from the wafer boat (20). In this way it becomes possible to quickly pick up four wafers (80) from the wafer cassette (40) on four end effectors (14) in one move and then place the four wafers (80) in the wafer boat (20) one by one at the correct load pitch (LP) saving time.

The method may further comprise moving the end effectors (14) carrying wafers in between the boat slots (46) of the wafer boat (20) and move the end effectors (14) down to leave a fifth wafer on a wafer slot in the wafer boat and retreat the end effectors (14) from the wafer boat (20). In this way it becomes possible to quickly pick up five wafers (80) from the wafer cassette (40) on five end effectors (14) in one move and then place the five wafers (80) in the wafer boat (20) one by one at the correct load pitch (LP) saving time.

The end effector (14) may have a vacuum clamp including a vacuum plenum in a wafer support surface (16) which vacuum plenum may be connectable to a vacuum source. The vacuum clamp may be switched on so as to connect the vacuum plenum with the vacuum source and may be switched off so that the vacuum plenum is disconnected from the vacuum source under control of the controller (24). The vacuum clamp may be switched off by the controller (24) when the wafer support surfaces (16) move down to leave a first wafer on a boat slot in the wafer boat (20). The vacuum clamp may provide a strong and reliable way to hold wafers (80) on the end effectors (14) during transfer.

The following method may be performed under control of the electronic controller (24) of the semiconductor processing assembly (10):
move the end effectors (14) in between the wafers in the boat slots (46) of the wafer boat (20) and move the end effectors (14) up to pick a first wafer from a boat slot in the wafer boat and retreat the end effectors (14) with the first wafer from the wafer boat (20);
move the end effectors (14) in between the wafers in the boat slots (46) of the wafer boat (20) and move the end effectors (14) up to pick up a second wafer on a wafer slot in the wafer boat and retreat the end effectors (14) with the second wafer from the wafer boat (20);
move the end effectors (14) of the wafer handling robot (12) in between the cassette slots in the wafer cassette (40) and move the end effectors (14) down to place the first and second wafer on the cassette slots and retreat the end effectors (14) from the wafer cassette (40).

The wafer handling robot (12) may comprise a pitch motor (15) operably connected to the electronic controller (24) to adjust the end effector pitch (EP) in substantial vertical direction. The method may further comprise:
adjusting the end effector pitch (EP) to have it substantially match the cassette pitch (CP).
transferring a plurality of wafers simultaneously between the cassette slots of the wafer cassette (40) and the end effectors (14) of the wafer handling robot (12). If the end effector pitch (EP) and the cassette pitch (CP) substantially match it becomes possible to transfer a plurality of wafers simultaneously saving time.

By using the assembly (10) and execute the method of the description automatically, the transfer of wafers between the wafer cassette (40) and the wafer boat (20) may save time.

Although illustrative embodiments of the present invention have been described above, in part with reference to the accompanying drawings, it is to be understood that the invention is not limited to these embodiments. Variations to the disclosed embodiments can be understood and effected by those skilled in the art in practicing the claimed invention, from a study of the drawings, the disclosure, and the appended claims.

Reference throughout this specification to “one embodiment” or “an embodiment” means that a particular feature, structure or characteristic described in connection with the embodiment is included in at least one embodiment of the present invention. Thus, the appearances of the phrases “in one embodiment” or “in an embodiment” in various places throughout this description are not necessarily all referring to the same embodiment.

Furthermore, it is noted that particular features, structures, or characteristics of one or more of the various embodiments which are described above may be used implemented independently from one another and may be combined in any suitable manner to form new, not explicitly described embodiments. The reference numbers used in the detailed description and the claims do not limit the description of the embodiments, nor do they limit the claims. The reference numbers are solely used to clarify.

### LEGEND

10 semiconductor processing assembly
12 wafer handling robot
14 end effector
15 pitch motor
16 wafer support surface
17 moveable housing
18 wafer centre finder
19 spindle
20 wafer boat
21 nut
22 front rail (of wafer boat)
23 pedestal
24 electronic controller
25 door plate
26 system memory
27 elevator
40 wafer cassette
44 wafer loading position
46 wafer slot
48 boat rail
50 top plate
52 bottom plate
80 wafer

What is claimed is:

1. A semiconductor processing assembly comprising:
a wafer handling robot comprising a plurality of end effectors to carry wafers distributed in substantial vertical direction at an end effector pitch;
a wafer boat having boat slots distributed in substantial vertical direction and configured to hold wafers to be loaded at a load pitch in the wafer boat;
a wafer cassette, having cassette slots distributed in substantial vertical direction at a cassette pitch and configured to hold wafers; and
an electronic controller for controlling at least the wafer handling robot and having a system memory,
wherein for transferring wafers between the wafer cassette, and the wafer boat, the electronic controller is configured and programmed with a program in its system memory to control the semiconductor processing assembly to transfer a plurality of wafers simultaneously between the cassette slots of the wafer cassette, and the end effectors of the wafer handling robot by having the end effector pitch of the wafer handling robot substantially match with the cassette pitch, and to transfer only one wafer a time between the end effectors of the wafer handling robot and one boat slot of the wafer boat to accommodate the load pitch for the wafer boat.

2. The semiconductor processing assembly according to claim 1, wherein the electronic controller is configured and programmed with a program in its system memory to control the semiconductor processing assembly to:
move the end effectors of the wafer handling robot in between a plurality of wafers in the wafer cassette, and move the end effectors up to place a plurality of wafers on the end effectors and retreat the end effectors from the wafer cassette;
move the end effectors carrying wafers in between the boat slots of the wafer boat and move the end effectors down to leave a first wafer of the wafers on the end effectors in the one boat slot in the wafer boat and retreat the end effectors from the wafer boat; and
move the end effectors carrying wafers in between the boat slots of the wafer boat and move the end effectors down to leave a second wafer of the wafer(s) on the end effectors in a second wafer slot in the wafer boat and retreat the end effectors from the wafer boat.

3. The semiconductor processing assembly according to claim 1, wherein the electronic controller is configured and programmed with a program in its system memory to control the semiconductor processing assembly to:
move the end effectors carrying wafers in between the boat slots of the wafer boat and move the end effectors down to leave a third wafer of the wafer(s) on the end effectors in a third boat slot in the wafer boat and retreat the end effectors from the wafer boat.

4. The semiconductor processing assembly according to claim 3, wherein the electronic controller is configured and programmed with a program in its system memory to control the semiconductor processing assembly to:
move the end effectors carrying wafers in between the boat slots of the wafer boat and move the end effectors down to leave a fourth wafer of the wafer(s) on the end effectors in a fourth boat slot in the wafer boat and retreat the end effectors from the wafer boat.

5. The semiconductor processing assembly according to claim 4, wherein the electronic controller is configured and programmed with a program in its system memory to control the semiconductor processing assembly to:
move the end effectors carrying wafers in between the boat slots of the wafer boat and move the end effectors down to leave a fifth wafer of the wafer(s) on the end effectors in a fifth boat slot in the wafer boat and retreat the end effectors from the wafer boat.

6. The semiconductor processing assembly according to claim 1, further comprising:
a plurality of wafer boats, wherein the wafer boats are each moveable to a wafer loading position in which wafers can be loaded by the wafer handling robot in the respective wafer boat, wherein the electronic controller is configured and programmed with a program in its system memory to control the semiconductor processing assembly to transfer wafers from the wafer cassette, to the wafer boat, for each wafer boat when it is positioned in the wafer loading position and the system memory is programmed with the load pitch of each one of the plurality of wafer boats when it is positioned in the wafer loading position.

7. The semiconductor processing assembly according to claim 1, wherein the end effectors have a vacuum clamp including a vacuum plenum in a wafer support surface which vacuum plenum is connectable to a vacuum source, wherein the vacuum clamp can be switched on under control of the electronic controller so as to connect the vacuum plenum with the vacuum source and can be switched off so that the vacuum plenum is disconnected from the vacuum source, and wherein the vacuum clamp is switched off when the wafer support surfaces of the end effectors move down to leave a first wafer on a boat slot in the wafer boat.

8. The semiconductor processing assembly according to claim 1, wherein for transferring wafers from the wafer boat to the wafer cassette the electronic controller is configured and programmed with a program in its system memory to control the semiconductor processing assembly to:
move the end effectors in between the wafers in the boat slots of the wafer boat and move the end effectors up to pick a first wafer from a boat slot in the wafer boat and retreat the end effectors with the first wafer from the wafer boat;
move the end effectors in between the wafers in the boat slots of the wafer boat and move the end effectors up to pick up a second wafer on a wafer slot in the wafer boat and retreat the end effectors with the second wafer from the wafer boat; and
move the end effectors of the wafer handling robot in between the cassette slots in the wafer cassette, and move the end effectors down to place a plurality of wafers in the cassette slots and retreat the end effectors from the wafer cassette.

9. The semiconductor processing assembly according to claim 1, wherein the wafer handling robot comprises a pitch motor operably connected to the electronic controller to adjust the end effector pitch in substantial vertical direction and the electronic controller is configured and programmed with a program in its system memory to have the end effector pitch substantially match the cassette pitch to transfer a plurality of wafers simultaneously between the cassette slots of the wafer cassette, and the end effectors of the wafer handling robot.

10. A method for transferring of wafers in a semiconductor processing assembly comprising:
a wafer handling robot comprising a plurality of end effectors configured to carry wafers and distributed in substantial vertical direction at an end effector pitch;
a wafer boat having boat slots distributed in substantial vertical direction and configured to hold wafers to be loaded at a load pitch;
a wafer cassette, having cassette slots distributed in substantial vertical direction at a cassette pitch and configured to hold wafers; and,
an electronic controller for controlling at least the wafer handling robot and having a system memory; wherein the following method is performed under control of the electronic controller of the semiconductor processing assembly:
transferring a plurality of wafers simultaneously between the cassette slots of the wafer cassette, and the end effectors of the wafer handling robot by having the end effector pitch substantially match the cassette pitch; and
transferring only one wafer a time between the end effectors of the wafer handling robot and one boat slot of the wafer boat to accommodate the load pitch for the wafer boat.

11. The method according to claim 10, comprising:
moving the end effectors of the wafer handling robot in between a plurality of wafers in the wafer cassette, and move the end effectors up to place a plurality of wafers on the end effectors and retreat the end effectors from the wafer cassette;
moving the end effectors carrying wafers in between the boat slots of the wafer boat and move the end effectors down to leave a first wafer of the wafer(s) on the end effectors in a boat slot in the wafer boat and retreat the end effectors from the wafer boat; and
directly thereafter; and
moving the end effectors carrying wafers in between the boat slots of the wafer boat and move the end effectors down to leave a second wafer of the wafer(s) on the end effectors in a wafer slot in the wafer boat and retreat the end effectors from the wafer boat.

12. The method according to claim 11, further comprising moving the end effectors carrying wafers in between the boat slots of the wafer boat and move the end effectors down to leave a third wafer on a wafer slot in the wafer boat and retreat the end effectors from the wafer boat.

13. The method according to claim 12, further comprising moving the end effectors carrying wafers in between the boat slots of the wafer boat and move the end effectors down to leave a fourth wafer on a wafer slot in the wafer boat and retreat the end effectors from the wafer boat.

14. The method according to claim 13, further comprising moving the end effectors carrying wafers in between the boat slots of the wafer boat and move the end effectors down to leave a fifth wafer on a wafer slot in the wafer boat and retreat the end effectors from the wafer boat.

15. The method according to claim 11, wherein the end effector has a vacuum clamp including a vacuum plenum in a wafer support surface which vacuum plenum is connectable to a vacuum source, wherein the vacuum clamp can be switched on so as to connect the vacuum plenum with the vacuum source and can be switched off so that the vacuum plenum is disconnected from the vacuum source, wherein the vacuum clamp is switched off when the wafer support surfaces moves down to leave a first wafer on a boat slot in the wafer boat.

16. A method according to claim 11, wherein the following method is performed under control of the electronic controller of the semiconductor processing assembly:
move the end effectors in between the wafers in the boat slots of the wafer boat and move the end effectors up to pick a first wafer from a boat slot in the wafer boat and retreat the end effectors with the first wafer from the wafer boat;
move the end effectors in between the wafers in the boat slots of the wafer boat and move the end effectors up to pick up a second wafer on a wafer slot in the wafer boat and retreat the end effectors with the second wafer from the wafer boat; and
move the end effectors of the wafer handling robot in between the cassette slots in the wafer cassette and move the end effectors down to place the first and second wafer on the cassette slots and retreat the end effectors from the wafer cassette.

17. The method according to claim 11, wherein the wafer handling robot comprises a pitch motor operably connected to the electronic controller to adjust the end effector pitch in substantial vertical direction and the method comprises:
adjusting the end effector pitch to have it substantially match the cassette pitch; and
transferring a plurality of wafers simultaneously between the cassette slots of the wafer cassette, and the end effectors of the wafer handling robot.
